(19) United States
(12) Patent Application Publication
(10) Pub. No.: US 2007/0102290 A1
(43) Pub. Date: May 10, 2007

(54) Novel material development apparatus and novel material development method using arc plasma

(75) Inventors: Seiichi Hata, Yokohama-shi (JP); Akira Shimokohbe, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: THE CIRCLE FOR THE PROMOTION OF SCIENCE AND ENGINEERING

(21) Appl. No.: 11/270,535

(22) Filed: Nov. 10, 2005

(51) Int. Cl. H05H 1/24; C23C 14/00; C23C 16/00

(52) U.S. Cl. 204/298.12; 427/569; 118/723 R

(57) ABSTRACT

This invention provides a novel material development apparatus capable of automatically and efficiently forming uniform novel materials with reduced impurities and different compositions individually on respective cells. The novel material development apparatus includes: a plurality of arc plasma guns; a magnetic circuit deflecting/focusing plasma of the arc plasma guns; a controller thereof; and a plurality of deposition cells. For film deposition, plasma containing ions of constituent elements and generated in a pulsed manner by the arc plasma guns are focused to the deposition cell by the magnetic circuit. We can switch the deposition cells by using the moving stage or by using the magnetic circuit changing a focus point, or we can change a focus point by using magnetic circuit so that collectively form uniform novel materials with reduced impurities and different compositions of alloys or compounds efficiently.

### BACKGROUND OF THE INVENTION

1. Field of the Invention

The present invention relates to a novel material development apparatus, and more particularly, to a novel material development apparatus and a novel material development method which are capable of forming a plurality of kinds of materials collectively by combining a plurality of elements with the use of a plurality of arc plasma emitters.

2. Description of the Prior Art

There is an increasing demand for epoch-making novel materials such as high-temperature superconductors, giant magnetoresistance materials, and super heat-resistant alloys. Detailed searches have already been conducted for materials composed of two elements or three elements, except for special elements including high melting-point materials such as tungsten, precious metals such as platinum, and rare earth metals such as lanthanum. There has arisen a need, however, for a search of materials composed of more elements. In the search of complex materials composed of multi elements, it often occurs that the properties of the materials are beyond theoretical prediction. Experimental investigations by trial and error for extremely many compositions are required to find out an intended material. Therefore, it has been commonly thought that the development of a novel material requires an enormous amount of time and cost.

Meanwhile, in the field of chemistry such as the development of a novel drug, a combinatorial synthesis method is coming in a general use as a means for efficiently searching novel chemical compounds. The combinatorial synthesis method is a means for synthesizing a large number of chemical compounds of the combination at once. The technique of the combinatorial synthesis method is applied also to the search of materials of metal alloys, oxides and so on. For example, X. D. Xiang et al. employs this technique in the search of an oxide superconductor by using a multi-target sputtering (Science, vol. 268, 1738, (1995)) and also in the search of cobalt oxide compounds having giant magnetoresistivity (U.S. Pat. No. 5,776,359). Further, Koinuma et al. carried out a search of materials having inorganic superstructure utilizing a laser molecular beam epitaxial growth apparatus adopting this technique (Japanese Patent No. 3018000).

The deposition methods of the sputtering and the epitaxy of the two prior arts are basically in common with depositing series of films at the point that each film is varied with respect to elemental composition in a predetermined way using masks on each substrate, thereby forming a material library (material group).

In the sputtering method and the epitaxial method, however, materials evaporated from the target diffuse before they reach the substrate. Then the majority of the evaporated materials adheres to the mask and to the inside portions of the chamber. In these methods, a large percentage of materials is wasted and which results in a low usage efficiency of the target materials. Furthermore, when the materials evaporated from the target diffuse and contaminate the inside of the chamber adhering to the mask and to the inside portion of the chamber, it takes a lot of time and labor to remove the contaminant, which results in an low apparatus operating rate. Moreover, the materials evaporated from the target materials spread around the mask contaminate the surrounding library. Further, the low usage efficiency of the target materials is undesirable in view of development cost of the novel material when the target in use include rare elements such as rare earth metals or precious metals.

In these methods, cathode targets used in sputtering, K cells used in vacuum deposition and MBE (molecular beam epitaxial deposition) and so on, generally require high power of 1 kVA or more. Furthermore, a large amount of heat generation necessitates a water-cooled structure for cooling, which in turn necessitates structure with heat isolation and electric insulation. Then the size of the whole apparatus becomes large.

In these film deposition methods, each substrate is disposed facing the substrate surface to a cathode targets or a K cells in the vacuum chamber. Accordingly, it is necessary to dispose a large number of targets and K cells facing the substrate surface for searching a novel material made of multi elements. This poses a problem of space limitation for their arrangement.

Meanwhile, a method using arc plasma has been drawing attention as a method for forming thin films in recent years. In this method, particulates of materials with a high kinetic energy are generated from cathode spots by arc discharge and the particulates are emitted from plasma guns, and then the particulates are deposited on a substrate. The basic structure of the arc plasma method has already been disclosed, for example, in Japanese Examined Patent Publication No. Sho 58-3033. When the arc plasma is used for film deposition, particulates of materials having higher kinetic energy can be used in the film deposition compared with the case when a sputtering method is adopted. Therefore, high-quality film formation can be expected using the method. The arc plasma method, however, involves the following problem. Besides the generation of the particulates of the material with a high kinetic energy at the cathode spots, there occurs scattering of coarse particles such as raw material liquid droplets, which directly reach and adhere to the surface of the substrate to impair flatness and uniformity of the deposited film. Therefore,various measures have been devised such as a structure for selectively guiding charged particulates of materials by using a magnetic field (Japanese Patent Laid-open Application No. Hei 4-45262) or the like.

A remarkable progress have been seen in a thin film forming apparatus using arc plasma owing to the development of a cylindrical arc plasma emitter (arc plasma gun) with a compact structure (Japanese Patent No. 2857743). This cylindrical arc plasma emitter is configured such that a cylindrical anode is disposed around a columnar raw material target cathode, trigger electrodes are cylindrically arranged near the cathode via an insulator member, a cathode spot is generated between the trigger electrodes and the cathode by discharge, pulsed discharge of a main discharge capacitor connected between the cathode spot and the anode generates plasma containing atoms and ions of the raw material target, and charged plasma particles are emitted by being accelerated in the cylinder by a Lorentz force acting between arc current and the charged plasma particles.

The film deposition apparatus using such a cylindrical arc plasma emitter has undergone many improvements including a deflector for deflecting the flying direction of the charged plasma particles (Japanese Patent Laid-open Application No. 2000-8157) and including a heater for heating the cathode raw material target (Japanese Patent Laid-open Application No. Hei 11-350113), which has enabled the apparatus to perform film deposition by arc plasma relatively easily. It has also become relatively easy to include the plural arc plasma emitters in a film deposition apparatus because this cylindrical arc plasma emitter can have a compact structure (Japanese Patent Laid-open Application No. 2000-8159).

However, nothing is known about one configured by using arc plasma emitters as a novel material development apparatus for forming a plurality of kinds of materials collectively by combining a plurality of elements, and therefore, it has been totally unknown what effects and operations the actual use of this structure exhibits and what problems it involves.

### SUMMARY OF THE INVENTION

The object of the present invention is to provide a novel material development apparatus and a novel material development method that are capable of efficiently forming a large number of materials made of plural elements and with different compositions and that are suitable for searching for a novel material made of multi elements.

The present invention provides a novel material development apparatus and a novel material development method that make it possible to form a large number of materials made of plural elements and with different compositions on deposition cells efficiently by deflecting and focusing each plasma of a plurality of raw material targets which is emitted from each of a plurality of arc plasma emitters and by guiding them to the deposition cells.

A novel material development apparatus of the present invention includes: a vacuum chamber; a plurality of arc plasma emitters each holding a raw material target as a cathode and emitting arc plasma of particulates of the raw material target into the vacuum chamber by arc discharge; a plurality of deposition cells held by a deposition cell holder disposed in said vacuum chamber; a deflecting/focusing device deflecting/focusing the arc plasma emitted by the plural arc plasma emitters; and a plasma controller controlling the arc plasma generated by the plural arc plasma emitters, wherein a plurality of kinds of materials are collectively formed while film deposition on the plural deposition cells held by the deposition cell holder is controlled cell by cell.

A first novel material development apparatus according to the present invention includes: a vacuum chamber; a plurality of arc plasma emitters each holding a raw material target as a cathode and emitting arc plasma of particulates of the raw material target into the vacuum chamber by arc discharge; a deposition cell holder disposed in the vacuum chamber to hold a plurality of deposition cells; a deflecting/focusing device deflecting/focusing the arc plasma emitted by the plural arc plasma emitters to one place; a moving mechanism subsequently moving the plural deposition cells held by the deposition cell holder; and a plasma controller controlling the arc plasma generated by the plural arc plasma emitters, wherein a plurality of kinds of materials are collectively formed while film deposition on the plural deposition cells held by the deposition cell holder is controlled cell by cell by the moving mechanism moving the plural deposition cells and by the plasma controller controlling the arc plasma.

A second novel material development apparatus according to the present invention includes: a vacuum chamber; a plurality of arc plasma emitters each holding a raw material target as a cathode and emitting arc plasma of particulates of the raw material target into the vacuum chamber by arc discharge; a deposition cell holder disposed in the vacuum chamber to hold a plurality of deposition cells; a deflecting/focusing device deflecting/focusing the arc plasma emitted by the plural arc plasma emitters to one place; a focus position moving mechanism subsequently moving a deflection/focus position of the arc plasma; and a plasma controller controlling the arc plasma generated by the plural arc plasma emitters, wherein the plural kinds of materials are collectively formed while film deposition on the plural deposition cells held by the deposition cell holder is controlled cell by cell by the moving mechanism moving the plural deposition cells and by the plasma controller controlling the arc plasma.

A third novel material development apparatus according to the present invention includes: a vacuum chamber; a plurality of arc plasma emitters each holding a raw material target as a cathode and emitting arc plasma of particulates of the raw material target into the vacuum chamber by arc discharge; a deposition cell holder disposed in the vacuum chamber to hold a plurality of deposition cells; a deflecting/focusing device deflecting/focusing the arc plasma emitted by the plural arc plasma emitters to a plurality of deflection/focus areas partly overlapping one another; and a plasma controller controlling the arc plasma generated by the plural arc plasma emitters, wherein a plurality of kinds of materials are collectively formed on the deposition cell.

The arc plasma emitter used in the present invention is low in power consumption and scarcely generates heat, and thus does not require a cooling mechanism and the like, and a gun main body thereof is small. The plasma can be magnetically guided and focused, which allows a high degree of freedom in an arrangement place of the gun, so that it is possible to prevent size increase of a vacuum chamber even when the guns are disposed in large number. Therefore, the whole apparatus becomes small in size and low in power consumption, which facilitates its installation and realizes improvement in operating efficiency, for example, reduction in the time required for vacuuming. The use of this apparatus thus makes it possible to automatically and efficiently form uniform novel materials with reduced impurities and with different compositions individually on the respective deposition cells.

Further, a novel material development method of the present invention includes: disposing deposition cells in a vacuum chamber; emitting arc plasma of particulates of raw material targets into the vacuum chamber from a plurality of arc plasma emitters having the raw material targets as cathodes; deflecting/focusing the arc plasma to irradiate the deposition cells with the arc plasma; and controlling the arc plasma emitted by the plural arc plasma emitters.

According to the film deposition by the arc plasma method used in the apparatus of the present invention, particles deposited for the film deposition has an energy higher than that in film deposition using vacuum deposition and MBE (molecular beam epitaxial method) by two figures or more and than that in film deposition using a sputtering method by one figure or more, and film deposition in a high vacuum is possible, so that an alloy or a compound with higher uniformity and reduced impurities can be obtained. Therefore, the use of the apparatus of the present invention makes it possible to efficiently form novel materials with high uniformity, reduced impurities, and different compositions on respective deposition cells. Further, film deposition along with the supply of gas such as oxygen and nitrogen enables a search of the composition of an oxide and a nitride. Further, it is possible to search the composition of multilayer-structure chemical compounds by irradiating the deposition cells with pulses of plasma from plasma guns and regulating the deposition rate per pulse on the order of angstrom to control the thickness.

### BRIEF DESCRIPTION OF THE DRAWINGS

FIG. 1 is a perspective view schematically showing a novel material development apparatus of one embodiment of the present invention.

FIG. 2 is a view schematically showing the arrangement of deposition cells in the embodiment of the present invention.

FIG. 3 is a perspective view schematically showing a novel material development apparatus of another embodiment of the present invention.

FIG. 4A to FIG. 4C are plane views of the apparatus shown in FIG. 3.

FIG. 5 is a view schematically showing film deposition of Cu, Zr, Ti, and an alloy thereof.

### DETAILED DESCRIPTION OF THE INVENTION

The novel material development apparatus of the present invention includes a vacuum chamber and the apparatus is capable of depositing film of a material in the chamber under a reduced pressure. The novel material development apparatus is also capable of depositing film in the chamber that is set under a predetermined atmosphere condition, provided with a gas introducing mechanism that introduces gas into the chamber.

In the novel material development apparatus of the present invention, a magnetic field by a magnetic field generator using a permanent magnet, a solenoid coil, or the like is usable as a deflecting/focusing device deflecting/focusing plasma emitted from arc plasma emitters. An electric field is also usable for the same purpose, and the co-use of the magnetic field and the electric field is also available for the same purpose.

In the novel material development apparatus of the present invention, masks are usable when the deposition cells are irradiated with plasma. The masks are disposed near the deposition cells, so that only the deposition cell positioned at an opening of the masks can be irradiated with the plasma.

In the first novel material development apparatus of the present invention, a moving mechanism for subsequently moving the plural deposition cells is used. The use of a controller enables the moving mechanism to automatically perform the accurate position movement. Further, in the second novel material development apparatus of the present invention, instead of providing the moving mechanism, the deflecting/focusing device changes a focus point of the plasma to thereby subsequently change the deposition cell to be disposed at a plasma irradiation position. In order to subsequently change the plasma irradiation position, a change is applied to a magnetic circuit of the magnetic field source, thereby changing the magnetic field. Alternatively, when a deflection electric field is used, the electric field is changed.

In the novel material development apparatus of the present invention, the plural arc plasma emitters can be used while voltage is applied in a pulsed manner to each of them so as to cause them generating pulsed arc plasma. As a plasma controller controlling the arc plasma generated by the plural arc plasma emitters, a method of controlling the number of the voltage pulses applied to the arc plasma emitters is usable, thereby controlling the number of the arc plasma generated by the arc plasma emitters. This controller enables precise digital control over a deposited amount of each material.

Furthermore, provided with a shutter mechanism that can be controlled to open/close individually, each of the plural arc plasma emitters can be prevented from being contaminated by the other arc plasma emitters. In addition, each of the plural arc plasma emitters can have a mechanism changing the direction for compensating the plasma deflection caused by Lorentz force due to a magnetic field or an electric field.

The above-described novel material development apparatus can include a temperature control mechanism for the deposition cells that heats or cools the deposition cells to control the temperature of the deposition cells. Furthermore, the plural arc plasma emitters can include therein a temperature control mechanism controlling temperature of raw material targets held as cathodes.

As the arc plasma emitter used in the present invention, it is preferable to use a so-called arc plasma gun configured such that a cylindrical anode is disposed around a columnar raw material target as a cathode, trigger electrodes are cylindrically disposed near the cathode via an insulator member, a cathode spot is generated between the trigger electrodes and the cathode by discharge, a main discharge capacitor connected between the cathode spot and the anode performs pulsed discharge to generate plasma containing atoms and ions of the raw material target, and charged plasma particles are emitted by being accelerated in the cylinder by a Lorentz force acting between arc current and the charged plasma particles.

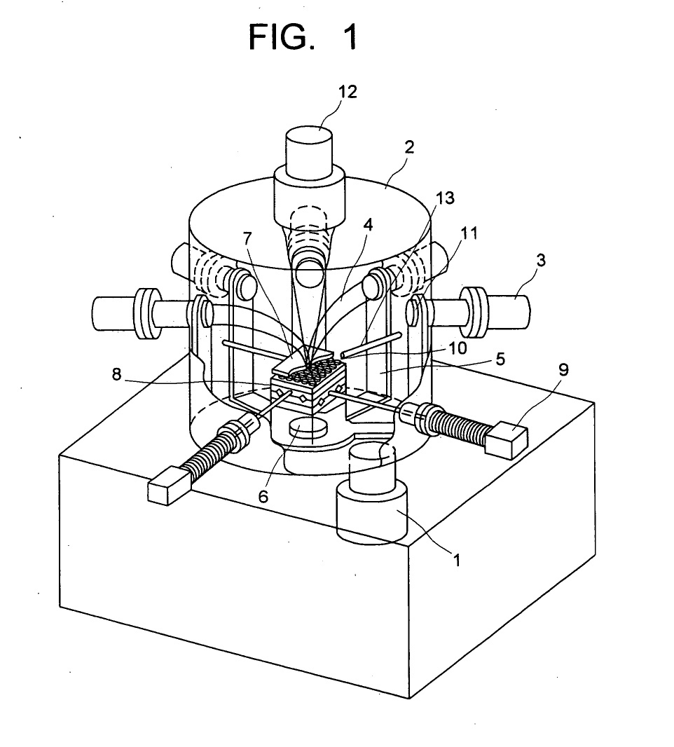

FIG. 1 is a perspective view schematically showing a configuration of a novel material development apparatus of one embodiment of the present invention. This novel material development apparatus includes a plurality of arc plasma guns 3 that are provided in a vacuum chamber 2 having a vacuum exhaust pump 1. For the plural arc plasma guns 3, provided is a magnetic circuit composed of a magnetic yoke 5 and a permanent magnet 6 for supplying a magnetic field by which plasma 4 emitted by the guns are deflected and focused in the chamber 2. Near a plasma focus point, a mask 7 having an opening is disposed. Under the mask 7, deposition cells 10 are disposed. Irradiating the deposition cells 10 with the plasma causes film deposition. The deposition cells 10 are held by an XY moving stage 8 being a deposition cell holder. The XY moving stage 8 and a stage driving mechanism 9 allow the deposition cells 10 to move.

Each of the arc plasma guns has a shutter mechanism 11 that can be individually controlled to open/close. A heater 12 heating the deposition cells individually or collectively and a gas introducing mechanism 13 for gas supply are further provided. The moving stage 8 has a not-shown water-cooled cooling mechanism.

In this apparatus, each of the arc plasma guns includes a conductive target having an element constituting a base material. Each of the arc plasma guns generates plasma in a pulsed manner, being controlled by a power source. Further, the deposition cells can be switched by the moving stage or by the change of the focus point by the magnetic circuit.

According to the film deposition method using arc plasma, plasma of one pulse per second, for example, is used for film deposition, which achieves a film deposition rate of about 0.01 nm to about 0.1 nm/pulse. Therefore, the use of this apparatus enables film deposition of about several atomic layers per pulse, and therefore, it is possible to control the composition and to control a multilayer film structure by simultaneously or alternately depositing respective elements from the plural arc plasma guns on the deposition cell and controlling the number of pulses thereof. Also possible is composition search of a multilayer structure chemical compound, utilizing the film deposition rate on the order of angstrom per pulse.

Using the novel material development apparatus with the above-described structure, for example, the inside of the vacuum chamber is evacuated to a predetermined pressure or to a pressure of a predetermined atmosphere such as nitrogen, and thereafter, the moving stage is used to move the deposition cell for the first film deposition to a position right under the opening of the mask. Then, the arc plasma is emitted from the arc plasma guns, thereby performing individual film deposition or plural film depositions in parallel.

Since the magnetic circuit composed of the yoke and the permanent magnet is formed to guide a magnetic flux through the inside of the deposition cell, the plasma is guided into the deposition cell. The mask and the guiding of the plasma prevent other cells and an inner wall of the chamber from being contaminated due to the spread of deposition materials, which enables efficient film deposition with small cathodes.

In order to control the composition of a thin film to be deposited on the deposition cell, the number of pulses per unit time of each of the arc plasma guns holding a constituent element as a cathode is controlled or power applied to the cathode is controlled. Each of the arc plasma guns has the shutter mechanism that can open and close individually, which prevents the cathodes of the arc plasma guns not in use for film deposition from being contaminated by neutral particles emitted from the other arc plasma gun.

After the film deposition with a predetermined composition and thickness on one cell, the moving stage moves the next deposition cell to the position right under the opening of the mask and film deposition follows with varied composition of a thin film. Thereafter, the movement of the deposition cell and the process of the film deposition are subsequently repeated, so that a material library in a thin film form having different compositions is completed on the deposition cells on the moving stage. Various characteristics of the completed material library are measured by DSC, X-ray diffraction, or the like, thereby probing a novel material having a desired physical property. In particular, the use of the deposition cell also as a cell for DSC thermal analysis enables quick start of thermal analysis. Since the deposition cell can be fabricated with an about several mm diameter, it is possible to set a large number of cells at once in a measuring apparatus at the time of composition analysis and structure analysis by CRD, EDS, or the like, which enhances measurement efficiency.

As has been described, higher energy particles are deposited for film deposition and film deposition in a high vacuum is possible using the arc plasma method. Accordingly, constituent elements are fully mixed at the time of the film deposition, so that it is possible to form an alloy or chemical compound library with higher uniformity and reduced impurities. Further, it is also possible to form a library of nitride or oxide chemical compounds or multilayer films. Heating the deposition cell at the time of or after the film deposition makes it possible to deposit a more uniform material and to control crystallization and crystal grains by heat treatment.

### DESCRIPTION OF THE PREFERRED EMBODIMENTS

The invention will be further explained by reference to the following examples.

### EXAMPLE 1

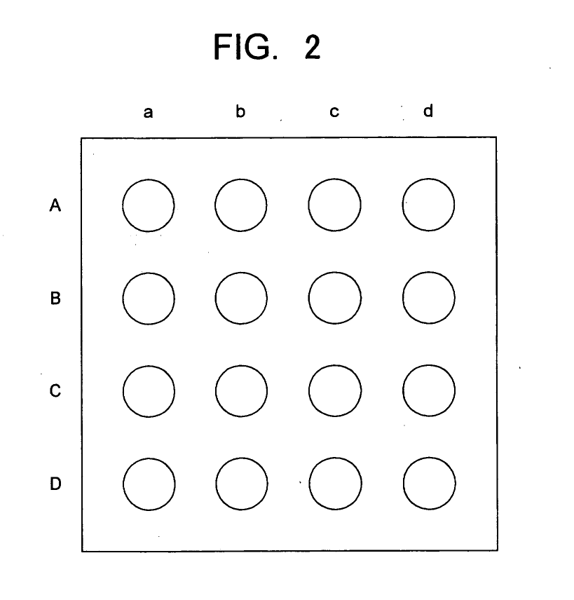

The apparatus shown in FIG. 1 is used for the first example of the present invention. In this example, constituent elements Zr, Cu, and Al were put in the three arc plasma guns 3 as the cathodes for the purpose of investigating amorphous formability of alloys composed of Zr, Cu, and Al. As the deposition cells 10, sixteen silver cells of a differential scanning calorimeter (DSC) were arranged in a 4×4 matrix on the stage 8. FIG. 2 is a view showing the arrangement of the deposition cells. Hereinafter, the deposition cells will be named Aa, Ab, . . . , and so on, according to the row and column.

In this state, the inside of the vacuum chamber 2 is evacuated to 10⁻⁵ Pa by the high vacuum pump 1, and the stage 8 is driven by the stage driving mechanism 9 to move the deposition cell Aa to the position right under the opening formed at the center of the mask 7. Thereafter, the arc plasma guns 3 emit the respective constituent elements in a pulsed manner by arc plasma radiation so that the film has a predetermined composition, thereby performing film deposition. For example, suppose Zr₇₀Cu₂₀Al₁₀ (subscripts indicate atomic percent) is a target composition in the film deposition on the deposition cell Aa, the number of pulses of the arc plasma guns 3 having Zr, Cu, and Al respectively is set to a ratio of 7:2:1 per unit time for film deposition, under the precondition that the arc plasma guns 3 generate the same number of deposition atoms per pulse.

After the film deposition on one deposition cell is completed, the stage 8 is driven by the stage driving mechanism 9 to move the next deposition cell (for example, the deposition cell Ab) to the position right under the opening of the mask 7, and film deposition is applied thereon under the similar control over the number of pulses of the arc plasma guns 3. A not-shown computer controls the film deposition all through a series of the procedure. In this example, the film deposition on all the deposition cells was completed in about 12 hours. In this example, the number of pulses of the arc plasma guns 3 was controlled at a ratio shown in Table 1. Further, since a ratio of the number of film deposition pulses of the elements Zr, Cu, and Al is 108:24:28, the number of the arc plasma guns 3 having the cathodes of Zr, Cu, and Al was set to 5, 1, and 2 respectively. Since the life of each of the cathodes is about 40,000 pulses, the total film deposition of the constituent elements attainable on each of the 16 cells was 16,600 pulses or more, or about 1.7 μm in terms of film thickness.

TABLE 1

| | a | b | C | d |
|---|---|---|---|---|
| A | 60:30:10 | 65:25:10 | 70:20:10 | 75:15:10 |
| B | 60:25:15 | 65:20:15 | 70:15:15 | 75:10:15 |
| C | 60:20:20 | 65:15:20 | 70:10:20 | 75:5:20 |
| D | 60:15:25 | 65:10:25 | 70:5:25 | 75:0:25 |

After the film deposition, DSC analysis was carried out with the 16 cells being sealed. As a result, it was possible to systematically investigate crystallization temperature and glass transition temperature. In this example, the search materials were all composed of conductive elements, but if an insulator element such as Si or B is necessary, a material of a mixture of such an element and a conductive element is used as the cathode. For example, for the composition search of an alloy composed of Pd, Cu, and Si, since pure Si is an insulator material, it is not usable as it is as a cathode in the arc plasma gun. In such a case, an alloy cathode of, for example, PdCuSi and cathodes of Pd and Cu are used.

Further, in this example, the film deposition was carried out under the vacuum atmosphere. However, film deposition along with the supply of oxygen or nitrogen with the use of the gas introducing mechanism 13 enables film deposition of an oxide or a nitride. The gas flow rate can be controlled by a not shown mass flowmeter and by the adjustment of a not-shown valve connected to the vacuum pump 1. Furthermore, it is possible to control a temperature condition of the film deposition individually for each deposition cell in such a manner that an infrared lamp heater and a reflective mirror are used as the heater 12 and infrared rays are gathered to the deposition cell positioned right under the mask 7. At this time, it is also possible to control the temperature of each of cells by measuring its temperature with a known thermometer such as a thermocouple thermometer or an infrared thermometer. Further, providing a water-cooled tube in the moving stage 8 makes it possible to prevent a temperature rise at the time of the film deposition and to improve temperature controllability at the time of heating.

### EXAMPLE 2

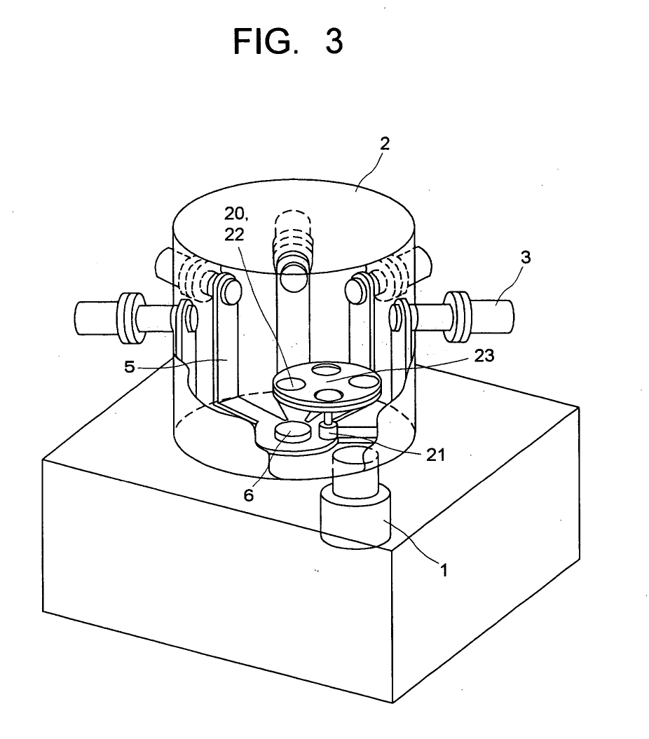

FIG. 3 shows a configuration of a novel material development apparatus of a second example of the present invention. The novel material development apparatus used in this example includes: a plurality of arc plasma guns 3 provided in a vacuum chamber 2 having a vacuum exhaust pump 1; a yoke 5 and a permanent magnet 6 for deflecting and focusing plasma emitted from the plural arc plasma guns 3 in the chamber 2; a rotary table 20 whose one end is positioned at a passage point of the plasma; a rotating mechanism 21 driving the rotary table; four deposition cells 22 placed on the rotary table 20; and a mask 23 having four openings.

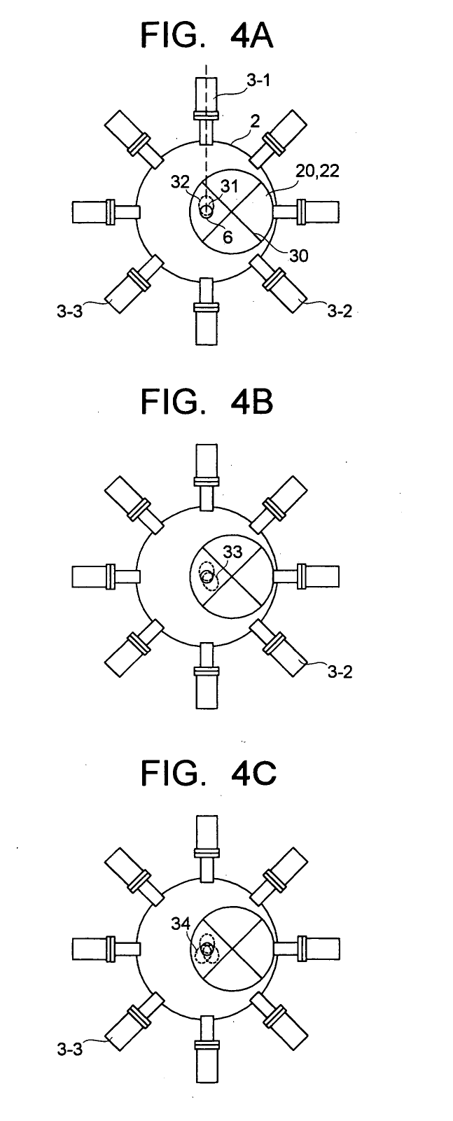

In this example, the vacuum chamber 2 is evacuated to 10^{-≡}Pa by the high vacuum pump 1, and the rotary table 20 divided into the four deposition cells 22 by partition plates 30 as shown in FIG. 4A to FIG. 4C is rotated by the rotating mechanism 21 using a stepping motor to place one of the deposition cells 22 right above the permanent magnet 6. Note that the rotary table 20, the partition plates 30, and the mask 23 not shown in FIG. 4A to FIG. 4C are all made of an aluminum alloy being a nonmagnetic material. Further, as the deposition cells 22, aluminum substrates each with a 0.5 mm thickness were used.

Cu, Zr, and Ti are put in cathodes 3-1, 3-2, 3-3 of the arc plasma guns respectively, and the composition realizing the minimum electrical resistivity of an alloy composed of these elements was searched. First of all, a voltage pulse is applied to the cathode 3-1 of the arc plasma gun, and then plasma is focused on an intersection point 31 of the periphery of the permanent magnet 6 and the center line of the arc plasma gun owing to a magnetic field by the permanent magnet 6 and the yoke 5. Since the deposition cell 22 is placed in the middle of this magnetic field, Cu is deposited on an area 32 surrounded by the dotted line in FIG. 4A on the deposition cell 22 at a rate of 0.1 nm/pulse.

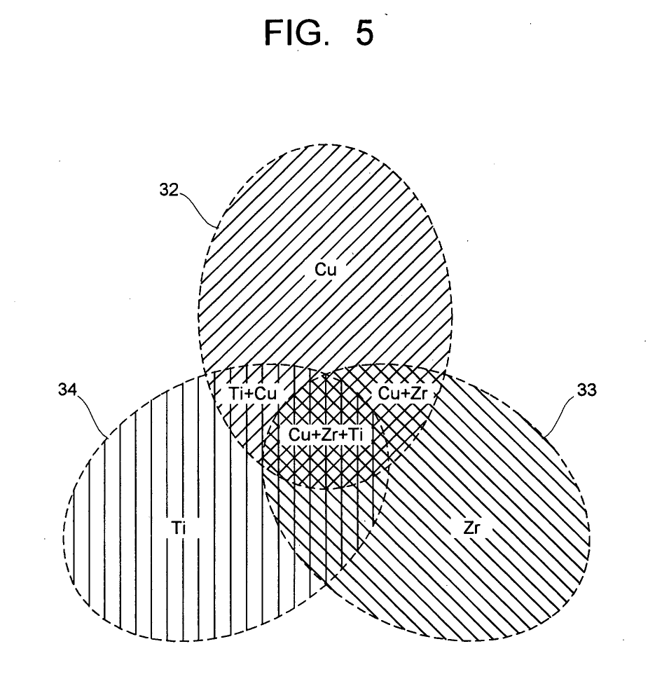

When a voltage pulse was similarly applied to the cathode 3-2 of the arc plasma gun and to the cathode 3-3 of the arc plasma gun, Zr and Ti were deposited on an area 33 and an area 34 respectively. Thus operating the cathodes of the three arc plasma guns in sequence resulted in the deposition of Cu, Zr, Ti, and alloys thereof as shown in FIG. 5. The deposition rate on each of the areas 32 to 34 on which the respective elements are deposited is the highest at the center thereof and gradually decreases toward the periphery thereof. Therefore, in portions where alloys of the two elements or the three elements are formed, the composition continuously changes in proportion to the film deposition rate of each element. It is possible to efficiently search the composition of the alloy with the minimum electrical resistivity by measuring the resistivity of each portion of the alloys by a four-probe method and by finding the composition of a portion with the smallest electrical resistivity by an energy dispersive X-ray analyzer.

Incidentally, in this example, the cathodes of the arc plasma guns were subsequently operated for the film deposition, but the simultaneous film deposition also exhibits the same effects. Further, the voltage application to the arc plasma guns and a pulse waveform can be appropriately adjusted according to the deposition rate of the cathode materials and a targeted composition range.

Incidentally, in the above-described examples, the arc plasma guns are disposed higher than the deposition cells. However, reversing the vertical positional relation thereof, the arc plasma guns may be disposed on the lower side to emit the plasma toward the deposition cells disposed above them. Thus, the novel material development apparatus of the present invention is not limited only to the above-described embodiments, but it goes without saying that various changes can be made without departing from the spirit of the present invention.

The arc plasma emitter used in the apparatus of the present invention can have a compact structure and can magnetically guide and focus the generated plasma. This can greatly reduce a loss of the raw materials as well as downsize the whole apparatus, thereby providing many advantages owing to its small size. Further, series of the operations in the apparatus of the present invention can be automated by the control by a computer. Therefore, the use of the apparatus of the present invention makes it possible to efficiently form a large number of materials of multi elements with different compositions as a library while greatly reducing a loss of the raw materials. The library of these multi-element materials is suitable for efficient measurement evaluation. In this manner, the present invention has achieved highly efficient novel material development.

What is claimed is:

1. A novel material development apparatus, comprising:
a vacuum chamber;
a plurality of arc plasma emitters each holding a raw material target as a cathode and emitting arc plasma of particulates of the raw material target into said vacuum chamber by arc discharge;
a plurality of deposition cells held by a deposition cell holder disposed in said vacuum chamber;
a deflecting/focusing device deflecting/focusing the arc plasma emitted by said plural arc plasma emitters; and
a plasma controller controlling the arc plasma generated by said plural arc plasma emitters,
wherein a plurality of kinds of materials are collectively formed while film deposition on the plural deposition cells held by said deposition cell holder is controlled cell by cell.

2. The novel material development apparatus as set forth in claim 1, wherein said deflecting/focusing device deflects/focuses the arc plasma emitted by said plural arc plasma emitters to one place, and the novel material development apparatus further comprising a moving mechanism subsequently moving the plural deposition cells held by said deposition cell holder, wherein the plural kinds of materials are collectively formed while film deposition on the plural deposition cells held by said deposition cell holder is controlled cell by cell by said moving mechanism moving the plural deposition cells and by said plasma controller controlling the arc plasma.

3. The novel material development apparatus as set forth in claim 1, wherein said deflecting/focusing device deflects/focuses the arc plasma emitted by said plural arc plasma emitters to one place, and the novel material development apparatus further comprising a focus position moving mechanism subsequently moving a deflection/focus position of the arc plasma; and wherein the plural kinds of materials are collectively formed while film deposition on the plural deposition cells held by said deposition cell holder is controlled cell by cell by said moving mechanism moving the plural deposition cells and by said plasma controller controlling the arc plasma.

4. The novel material development apparatus as set forth in claim 1, wherein said deflecting/focusing device deflects/focuses the arc plasma emitted by said plural arc plasma emitters to a plurality of deflection/focus areas partly overlapping one another, and the plural kinds of materials are collectively formed on the deposition cell.

5. The novel material development apparatus as set forth in claim 1, further comprising a deposition cell temperature control mechanism controlling temperature of the deposition cells.

6. A novel material development method, comprising:
disposing deposition cells in a vacuum chamber;
emitting arc plasma of particulates of raw material targets into the vacuum chamber from a plurality of arc plasma emitters having the raw material targets as cathodes;
deflecting/focusing the arc plasma to irradiate the deposition cells with the arc plasma; and
forming a plurality of kinds of materials collectively on the deposition cells while controlling the arc plasma emitted by the plural arc plasma emitters.
